(19) United States
(12) Patent Application Publication
(10) Pub. No.: US 2017/0172001 A1
(43) Pub. Date: Jun. 15, 2017

(54) ELECTRONIC DEVICE

(71) Applicant: Kabushiki Kaisha Toshiba, Minato-ku (JP)

(72) Inventors: Tadahiro SASAKI, Nerima (JP); Hiroyuki Kayano, Fujisawa (JP); Noritsugu Shiokawa, Yokohama (JP); Tamio Kawaguchi, Kawasaki (JP); Hiroaki Ikeuchi, Kawasaki (JP); Mutsuki Yamazaki, Yokohama (JP)

(73) Assignee: Kabushiki Kaisha Toshiba, Minato-ku (JP)

(21) Appl. No.: 15/445,750

(22) Filed: Feb. 28, 2017

Related U.S. Application Data
(63) Continuation of application No. PCT/JP2015/058272, filed on Mar. 19, 2015.

(51) Int. Cl. H05K 5/02; H05K 9/00

(52) U.S. Cl. CPC H05K 5/0217; H05K 9/0007

(57) ABSTRACT

According to one embodiment, an electronic device includes a housing, an electronic component, a first conductor, and a second conductor. The housing includes a first plate portion, a second plate portion, and a third plate portion. The first plate portion has a first surface. The second plate portion is separated from the first surface. The third plate portion has a third surface. The electronic component is provided inside the housing. The first conductor is provided inside the first plate portion. The second conductor includes first region and a second region. The second conductor is provided between the first plate portion and the second plate portion. An end of the first region is connected to the first conductor. An opening is provided between at least a portion of the first region and at least a portion of the second region.

### CROSS-REFERENCE TO RELATED APPLICATIONS

This is a continuation application of International Application PCT/JP2015/058272, filed on Mar. 19, 2015; the entire contents of which are incorporated herein by reference.

### FIELD

Embodiments described herein relate generally to an electronic device.

### BACKGROUND

An electronic component that is included in an electronic device may be provided in the interior of a housing to suppress noise and corrosion due to the external air. It is desirable for the noise generated in the interior of the housing to be low for an electronic device including such a housing.

### BRIEF DESCRIPTION OF THE DRAWINGS

FIG. 1 is a perspective view of an electronic device according to a first embodiment;

FIG. 2 is a cross-sectional view of the electronic device according to the first embodiment;

FIG. 3 is a plan view of a portion of the electronic device according to the first embodiment;

FIG. 4 is a bottom plan view of a portion of the electronic device according to the first embodiment;

FIG. 5 is an enlarged cross-sectional view of a portion of the electronic device according to the first embodiment;

FIG. 6 and FIG. 7 are enlarged plan views of a portion of the electronic device according to the first embodiment;

FIG. 8 is an enlarged perspective view of a portion of the electronic device according to the first embodiment;

FIG. 9 is a graph illustrating characteristics of electronic devices according to the first embodiment and a comparative example;

FIG. 10 is an enlarged plan view of a portion of an electronic device according to a second embodiment; and

FIG. 11 is an enlarged plan view of a portion of an electronic device according to a third embodiment.

### DETAILED DESCRIPTION

According to one embodiment, an electronic device includes a housing, an electronic component, a first conductor, and a second conductor. The housing includes a first plate portion, a second plate portion, and a third plate portion. The first plate portion has a first surface. The second plate portion is separated from the first surface in a first direction. The first direction crosses the first surface. The second plate portion has a second surface aligned with the first surface. The third plate portion has a third surface crossing a second direction. The second direction crosses the first direction. The electronic component is provided inside the housing. The first conductor is provided inside the first plate portion. The second conductor includes first region and a second region. The second conductor is provided between the first plate portion and the second plate portion. An end of the first region is connected to the first conductor. A position in the second direction of at least a portion of the first region is between a position in the second direction of the end of the first region and a position in the second direction of at least a portion of the third plate portion. An end of the second region is connected to the first conductor. A position in the second direction of at least a portion of the second region is between a position in the second direction of the end of the second region and a position in the second direction of at least a portion of the third plate portion. An opening is provided between at least a portion of the first region and at least a portion of the second region.

Embodiments of the invention will now be described with reference to the drawings.

The drawings are schematic or conceptual; and the relationships between the thicknesses and widths of portions, the proportions of sizes between portions, etc., are not necessarily the same as the actual values thereof.

The dimensions and/or the proportions may be illustrated differently between the drawings, even in the case where the same portion is illustrated. In the drawings and the specification of the application, components similar to those described thereinabove are marked with like reference numerals, and a detailed description is omitted as appropriate.

### First Embodiment

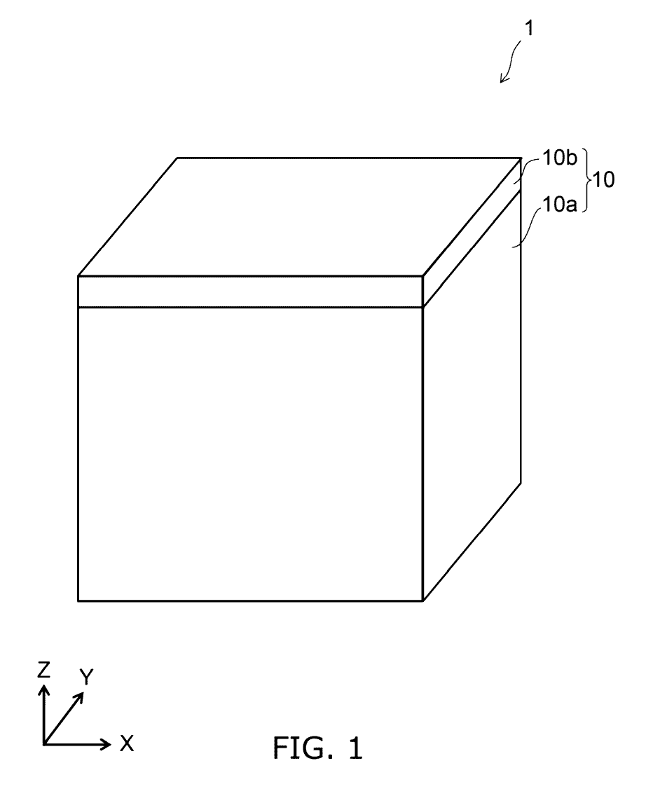

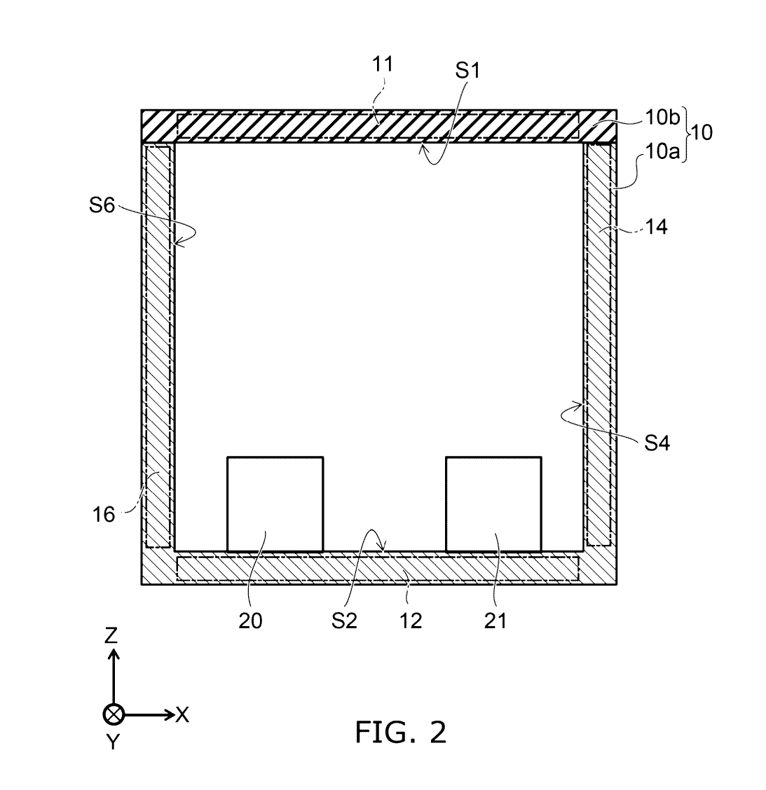

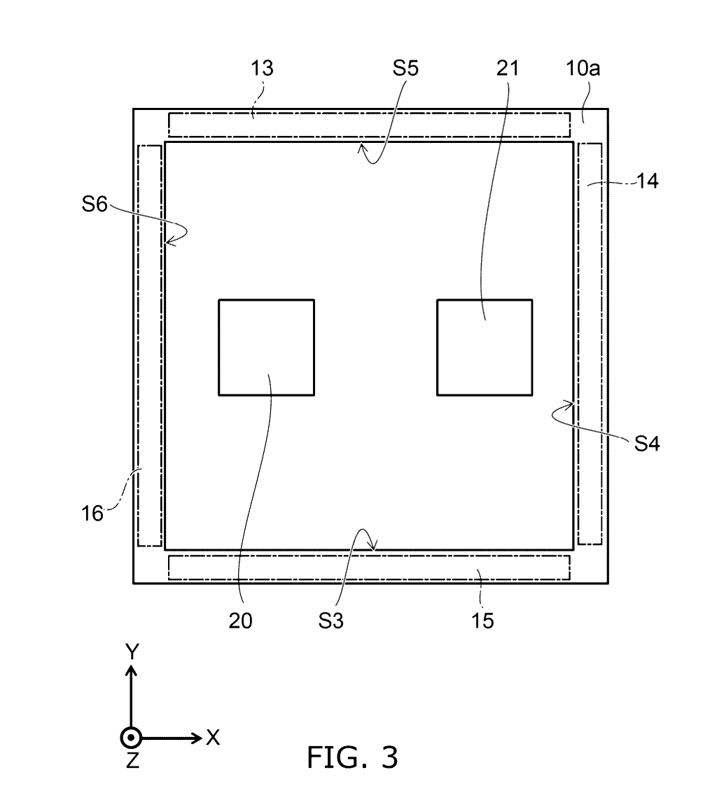

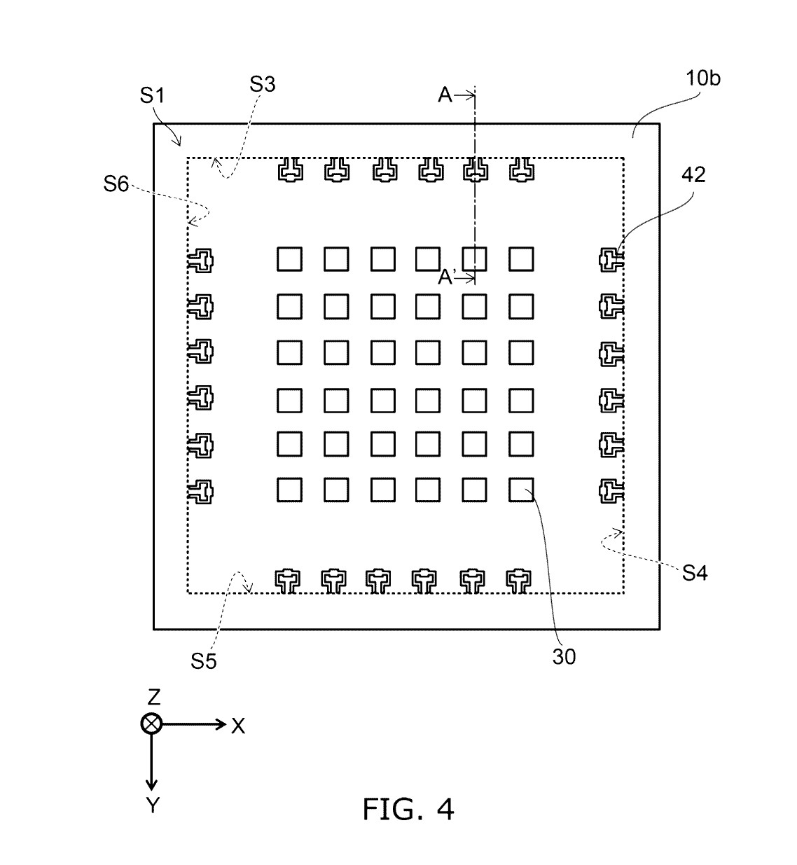

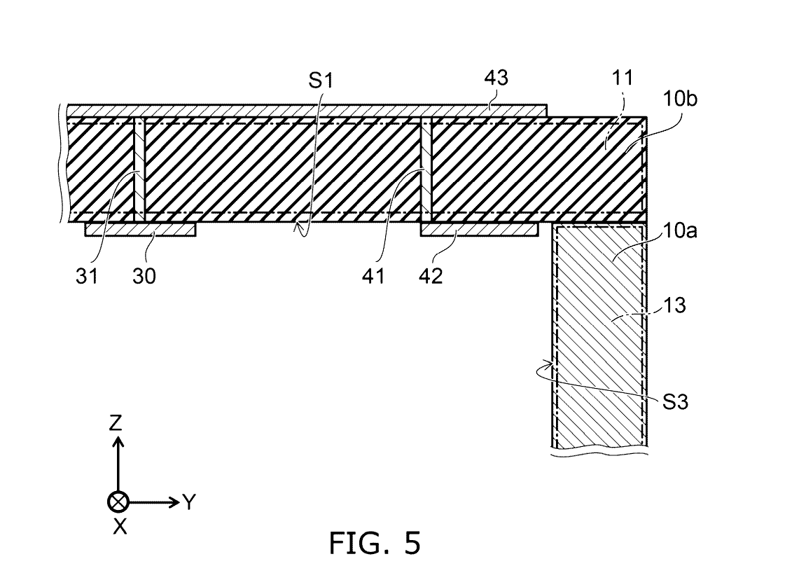

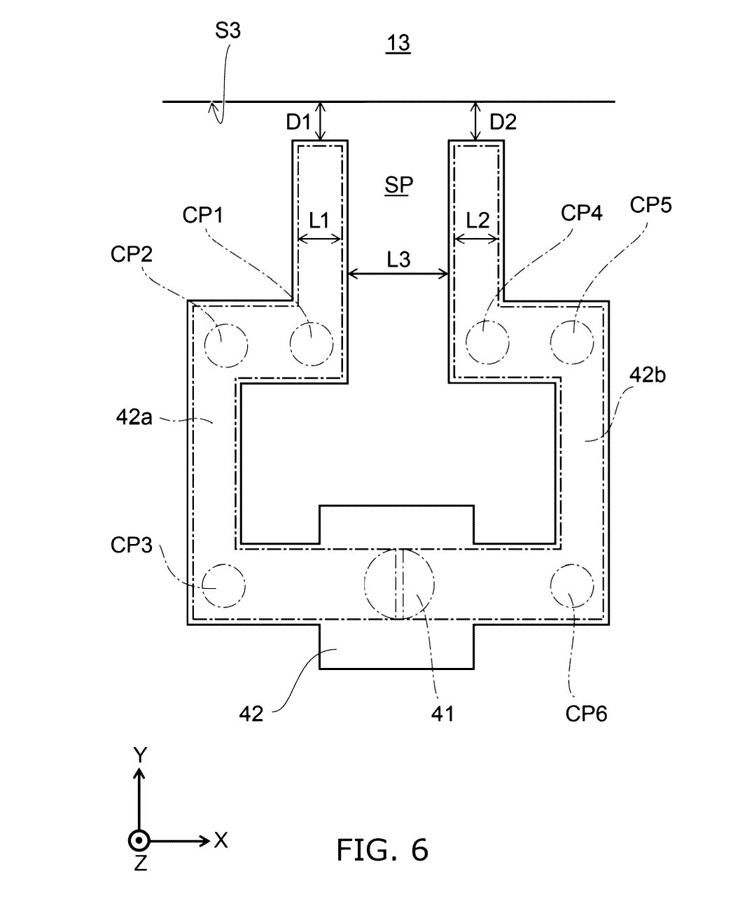

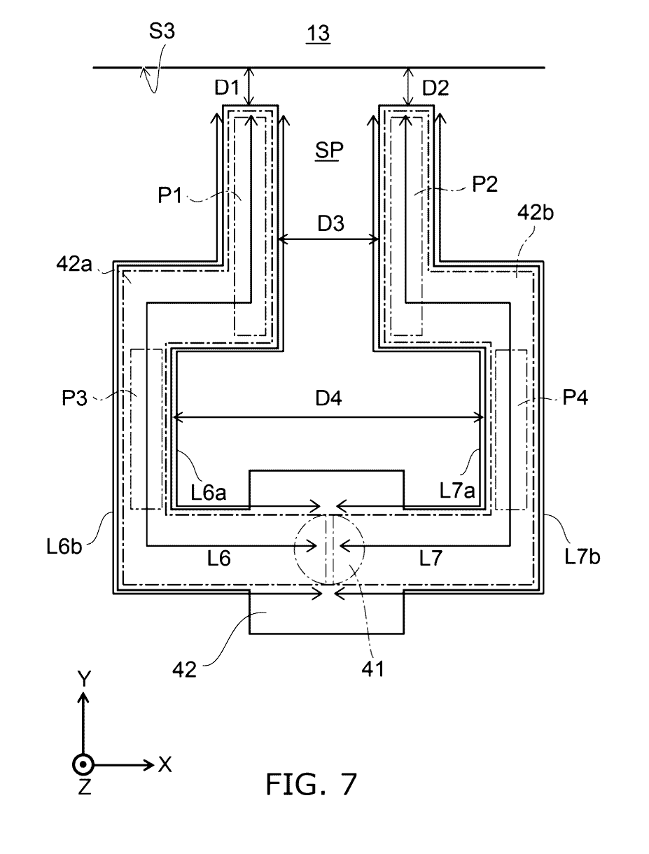

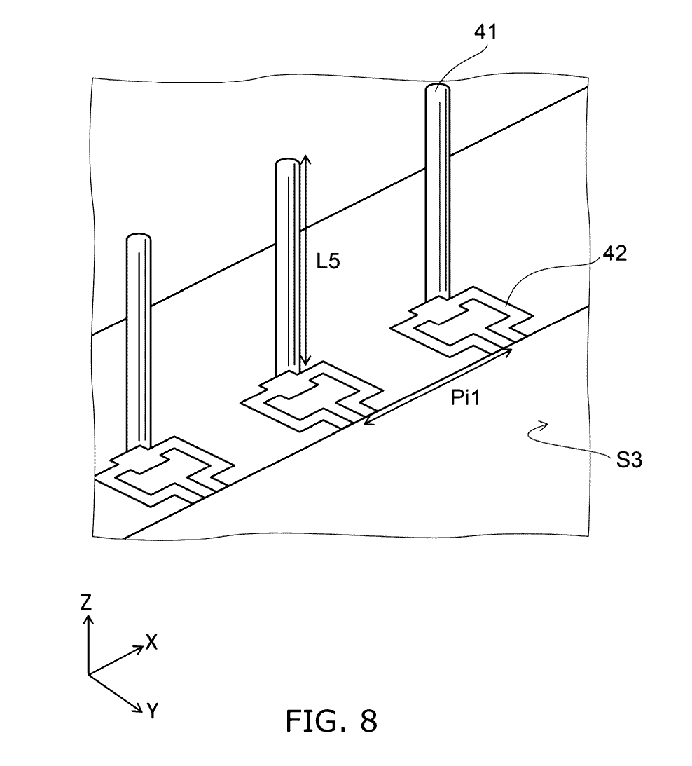

FIG. 1 is a perspective view of an electronic device 1 according to a first embodiment. FIG. 2 is a cross-sectional view of the electronic device 1 according to the first embodiment. FIG. 3 is a plan view of a portion of the electronic device 1 according to the first embodiment. FIG. 4 is a bottom plan view of a portion of the electronic device 1 according to the first embodiment. FIG. 5 is an enlarged cross-sectional view of a portion of the electronic device 1 according to the first embodiment. FIG. 6 and FIG. 7 are enlarged plan views of a portion of the electronic device 1 according to the first embodiment. FIG. 8 is an enlarged perspective view of a portion of the electronic device 1 according to the first embodiment.

As illustrated in FIG. 1, the electronic device 1 includes a housing 10. The housing 10 includes a main unit 10a and a lid 10b. The main unit 10a includes a metal, an insulator, or a semiconductor. The main unit 10a may include a portion made of a metal and a portion made of an Insulator. The lid 10b includes, for example, a metal, an insulator, or a semiconductor. The lid 10b is, for example, a printed circuit board.

As illustrated in FIG. 2 and FIG. 3, the housing 10 includes a first plate portion 11, a second plate portion 12, a third plate portion 13, a fourth plate portion 14, a fifth plate portion 15, and a sixth plate portion 16. The first plate portion 11 has a first surface S1. The second plate portion 12 has a second surface S2. The third plate portion 13 has a third surface S3. The fourth plate portion 14 has a fourth surface S4. The fifth plate portion 15 has a fifth surface S5. The sixth plate portion 16 has a sixth surface S6.

The second surface S2 is aligned with the first surface S1. The fifth surface S5 is aligned with the third surface S3. The sixth surface S6 is aligned with the fourth surface S4.

The second surface S2 is separated from the first surface S1 in a first direction. In other words, the first surface S1 and the second surface S2 cross the first direction. The first direction is, for example, a Z-direction illustrated in FIG. 2.

The fifth surface S5 is separated from the third surface S3 in a second direction crossing the first direction. In other words, the third surface S3 and the fifth surface S5 cross the second direction. The second direction is, for example, a Y-direction illustrated in FIG. 2.

The sixth surface S6 is separated from the fourth surface S4 in a third direction perpendicular to the first direction and the second direction. In other words, the fourth surface S4 and the sixth surface S6 cross the third direction. The third direction is, for example, an X-direction illustrated in FIG. 2.

Electronic components 20 and 21 are provided in the interior of the housing 10. The number of electronic components illustrated in FIG. 2 and FIG. 3 is an example. In the interior of the housing 10, only one electronic component may be provided; or three or more electronic components may be provided. For example, the electronic component 20 and the electronic component 21 are provided on the second plate portion 12. Not-illustrated Insulating layers and Interconnect layers may be provided between the electronic component 20 and the second plate portion 12 and between the electronic component 21 and the second plate portion 12.

Signals from a not-illustrated input port are input to the electronic components 20 and 21; and signals that are output from the electronic components 20 and 21 are output from a not-illustrated output port.

A substrate that includes the electronic components 20 and 21 may be provided in the interior of the housing 10. For example, a digital circuit, an analog circuit, a digital-analog mixed circuit, an RF circuit, or an antenna circuit is mounted in the substrate. The substrate may be made using SoC (Silicon on chip) technology or pseudo-SoC technology.

FIG. 4 illustrates the appearance of the lid 10b when viewed from the bottom surface. In FIG. 4, the positions of the third to sixth surfaces S3 to S6 projected onto the first surface S1 In the first direction are illustrated by broken lines. As Illustrated in FIG. 4, multiple second conductors 42 and multiple metal patches 30 are provided on the first surface S1. In other words, the multiple second conductors 42 and the multiple metal patches 30 are provided between the first surface S1 and the second surface S2.

The second conductor 42 and the metal patch 30 are conductive. The second conductor 42 and the metal patch 30 include, for example, a metal. The second conductor 42 and the metal patch 30 may include copper.

The second conductor 42 is multiply provided in the second direction and the third direction. A portion of the second conductors 42 is arranged in the second direction; and another portion of the second conductors 42 is arranged in the third direction. As illustrated in FIG. 4, for example, the second conductors 42 are provided to be proximal to one of the third to sixth surfaces S3 to S6.

The metal patch 30 is multiply provided on the first surface S1. The metal patches 30 are arranged in the second direction and the third direction. For example, the metal patches 30 are included in an EBG (Electromagnetic Band Gap). The metal patches 30 are provided to be separated from the second conductors 42 in the second direction and the third direction. For example, at least one of the multiple metal patches 30 and at least one of the multiple second conductors 42 are arranged in the second direction or the third direction.

As illustrated in FIG. 5, a first conductor 41 is provided Inside the first plate portion 11. For example, the first conductor 41 extends in the first direction. The second conductor 42 is electrically connected to the first conductor 41. The first conductors 41 are provided at positions respectively overlapping the second conductors 42 in FIG. 4. In other words, the first conductors 41 are multiply provided. A portion of the first conductors 41 is arranged in the second direction; and another portion of the first conductors 41 is arranged in the third direction. For example, the second conductors 42 are set to a fixed potential via the first conductors 41.

A third conductor 43 may be further connected to the first conductors 41. For example, the first conductors 41 are set to a ground potential via the third conductor 43. The first conductors 41 are provided between the third conductor 43 and the second conductors 42. A portion of the first plate portion 11 is provided between the third conductor 43 and the second conductors 42. For example, the third conductor 43 is provided on the surface on the opposite side of the first surface S1 of the first plate portion 11.

A via 31 is provided inside the first plate portion 11. The via 31 is connected to the metal patch 30. The via 31 is further connected to the third conductor 43. Therefore, the second conductor 42 and the metal patch 30 are electrically connected. In other words, the potential of the second conductor 42 is equal to the potential of the metal patch 30.

The first conductor 41, the third conductor 43, and the via 31 are conductive. The first conductor 41, the third conductor 43, and the via 31 include, for example, a metal. The first conductor 41, the third conductor 43, and the via 31 may include copper.

In FIG. 6 and FIG. 7, an enlargement of only one second conductor 42 of the multiple second conductors 42 provided at the third plate portion 13 vicinity is illustrated. In FIG. 6 and FIG. 7, the portion of the second conductor 42 overlapping the first conductor 41 in the first direction is Illustrated by a broken line. The second conductor 42 illustrated in FIG. 7 is the same as the second conductor 42 of the multiple second conductors 42 illustrated in FIG. 6.

The second conductor 42 includes a first region 42a and a second region 42b. An end of the first region 42a is connected to the first conductor 41. The position in the second direction of at least a portion of the first region 42a is between the position in the second direction of the end of the first region 42a and the position in the second direction of at least a portion of the third plate portion 13.

An end of the second region 42b is connected to the first conductor 41. The position in the second direction of at least a portion of the second region 42b is between the position in the second direction of the end of the second region 42b and the position in the second direction of at least a portion of the third plate portion 13.

The distance in the second direction between the first region 42a and the third plate portion 13 is not more than the length in the third direction of at least a portion of the first region 42a. As an example, a distance D1 between the third plate portion 13 and the end portion in the second direction of the first region 42a is shorter than a length L1 in the third direction of a portion of the first region 42a. It is more desirable for the end portion in the second direction of the first region 42a to contact the third surface S3. In other words, it is desirable for the distance D1 to be zero.

Similarly, the distance in the second direction between the second region 42b and the third plate portion 13 also is not more than the length in the third direction of at least a portion of the second region 42b. As an example, a distance D2 between the third plate portion 13 and the end portion in the second direction of the second region 42b is shorter than a length L2 in the third direction of a portion of the second region 42b. It is more desirable for the end portion in the second direction of the second region 42b to contact the third surface S3. In other words, it is desirable for the distance D2 to be zero.

An opening SP is provided between at least a portion of the first region 42a and at least a portion of the second region 42b. In other words, at least a portion of the second region 42b is separated from at least a portion of the first region 42a in the third direction.

The length in the third direction of at least a portion of the first region 42a is not more than the length in the third direction of at least a portion of the opening SP. As an example, the length L1 in the third direction of a portion of the first region 42a is not more than a length L3 in the third direction of a portion of the opening SP.

The length in the third direction of at least a portion of the second region 42b is not more than the length in the third direction of the at least a portion of the opening SP. As an example, the length L2 in the third direction of a portion of the second region 42b is not more than the length L3 in the third direction of the portion of the opening SP.

The length in the first direction of the first conductor 41 is designed so that the first conductor 41 has an antiresonant frequency in a desired cut-off band. It is desirable for the length L1 and the length L2 to be within ±20% of the diameter of the first conductor 41 so that the second conductor 42 similarly has an antiresonant frequency in a desired cut-off band. The diameter of the first conductor 41 is the length in the second direction of the first conductor 41 or the length in the third direction of the first conductor 41.

The first region 42a may include a bent portion. As an example, the first region 42a includes the multiple bent portions of a first bent portion CP1, a second bent portion CP2, and a third bent portion CP3 as illustrated in FIG. 6.

Similarly, the second region 42b also may include a bent portion. As an example, the second region 42b includes the multiple bent portions of a fourth bent portion CP4, a fifth bent portion CP5, and a sixth bent portion CP6 as illustrated in FIG. 6.

As illustrated in FIG. 7, the first region 42a includes, for example, a first portion P1 and a third portion P3. The second region 42b includes, for example, a second portion P2 and a fourth portion P4. The first to fourth portions P1 to P4 are aligned with the second direction.

A distance D4 in the third direction between the third portion P3 and the fourth portion P4 is longer than a distance D3 In the third direction between the first portion P1 and the second portion P2. The distance D3 and the distance D4 are longer than the distance D1 and the distance D2.

FIG. 8 illustrates the appearance of the first conductor 41 and the second conductor 42 in perspective from the bottom surface. In FIG. 8, the first plate portion 11 is illustrated as being transparent.

For example, a length L5 in the first direction of the first conductor 41 is equal to a length L6 from one end to the other end of the first region 42a and equal to a length L7 from one end to the other end of the second region 42b illustrated in FIG. 7. The length L6 may be the average of the lengths of the two sides of the first region 42a from the one end of the first region 42a toward the other end of the first region 42a.

In other words, in the example illustrated in FIG. 7, the length L6 may be the average of a length L6a and a length L6b. Similarly, the length L7 may be the average of the lengths of the two sides of the second region 42b from one end of the second region 42b toward the other end of the second region 42b. In other words, the length L7 may be the average of a length L7a and a length L7b.

Although the length L6 is equal to the length L7 In the example illustrated in FIG. 7, the length L6 may be different from the length L7. In the example illustrated in FIG. 6 and FIG. 7, the second conductor 42 passes through the first conductor 41 and has a structure that is symmetric with respect to a virtual plane including the second direction; but the second conductor 42 may have a structure that is asymmetric with respect to the virtual plane.

Thus, a portion of the second conductors 42 of the multiple second conductors 42 provided at the third plate portion 13 vicinity is described using FIG. 6 to FIG. 8. A configuration that is similar to the configuration illustrated in FIG. 6 to FIG. 8 is employable for the second conductors 42 provided at the vicinities of the fourth to sixth plate portions 14 to 16 as well.

According to the embodiment, because the electronic device 1 includes the first conductor 41 and the second conductor 42, it is possible to reduce the noise generated in the housing 10 interior.

To further reduce the noise generated in the housing 10 interior, it is desirable for the distance D1 to be the length L1 or less and for the distance D2 to be the length L2 or less. More favorably, the distance D1 and the distance D2 are zero. Further, it is desirable for the length L1 and the length L2 to be the length L3 or less.

For example, the length L6 and the length L7 are designed according to the frequency of the electromagnetic wave at which the reduction is desirable. Because the first region 42a and the second region 42b include bent portions, it is possible to lengthen the length L6 and the length L7 while suppressing the increase of the surface area occupied by the second conductor 42 on the first surface S1.

Because the second conductor 42 is multiply provided in the second direction and the third direction, it is possible to even further reduce the noise generated in the housing 10 interior.

In a housing that includes a resin sealing a system circuit board and in a housing that includes a metal, spatial noise that is caused by reflections of electromagnetic waves may occur between the interior wall surfaces, the ceiling, and the circuit board in the housing interior. Hotspots which are regions where the intensity of the noise is high may occur due to the spatial noise; and oscillations of the circuit provided in the housing interior and/or resonance of the housing may occur. As a countermeasure, it may be considered to widely use filter components; but in such a case, it is difficult to downsize the system board. As another countermeasure, it may be considered to increase the length of the path of the reflected waves; but in such a case, it is difficult to reduce the height of the housing.

A system may be considered that includes several layer structures into which the system functions from SOC to the printed circuit board are subdivided. Then, each layer is placed in a housing to suppress the noise caused by the circuit operation and the corrosion due to the external air. Such housings may be roughly divided into housings made of resin and housings made of metal. It may be considered to place circuits in which noise is generated easily due to the circuit operation and circuits in which misoperations occur easily due to noise of the external environment in a housing made of a metal.

The noise may be roughly divided into noise that Is coupled by the lead-lead capacitance on the circuit board, and noise that propagates through space. The noise of the former can be reduced by reducing the capacitive coupling between the leads. Therefore, the noise of the former can be suppressed by providing a filter circuit and by widening the lead spacing. On the other hand, the noise of the latter that propagates through space may not be affected at all according to the location where the filter is provided. Further, because hotspots occur due to reflections of the housing, a countermeasure is performed in which a material that suppresses the reflections or absorbs the electromagnetic waves is adhered to the side wall inside the housing. However, in such a case, because the dielectric constant of the adhered material is added to the dielectric constant of the original circuit design, the circuit operation shifts greatly from the original design; and there is a risk that operation errors may occur.

The electronic device 1 according to the embodiment is useful for these problems.

The length L6 and the length L7 are, for example, an odd multiple of ½ of the wavelength or an odd multiple of ¼ of the wavelength determined using the dielectric constant of the environment (the air, the substrate, etc.) contacting the metal based on the frequency propagating through the metal included in the housing. As an example, ¼ of the wavelength is 2.5 mm, and ½ of the wavelength is 5 mm in the case where a frequency in the vicinity of 14.5 GHz used in satellite communication is input to the electronic device 1, the main unit 10a includes a metal such as copper, aluminum, gold, etc., the lid 10b includes a metal such as copper, aluminum, gold, etc., and the dielectric constant of the environment contacting the metal is 4.2. Accordingly, the length L6 and the length L7 may be an odd multiple of ½ or an odd multiple of ¼ of the wavelength. In such a case, if the difference between the length L6 and the odd multiple of ½ of the wavelength or the odd multiple of ¼ of the wavelength is ±20%, these values can be considered to be substantially equal. Similarly, if the difference between the length L7 and the odd multiple of ½ of the wavelength or the odd multiple of ¼ of the wavelength is ±20%, these values can be considered to be substantially equal.

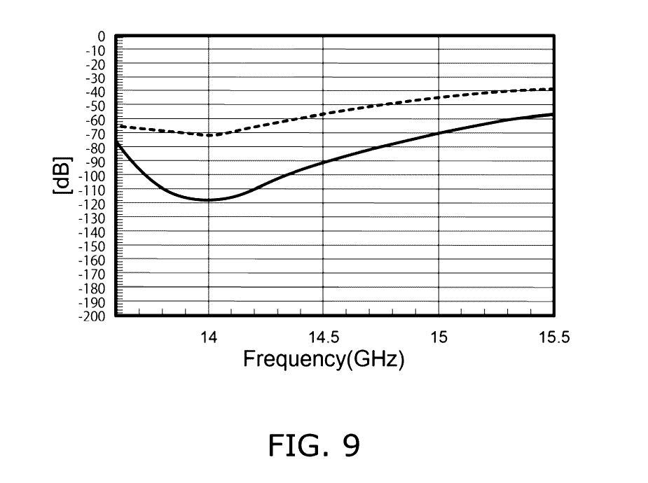

Simulation results relating to the electronic device 1 will now be described with reference to FIG. 9. FIG. 9 is a graph illustrating characteristics of electronic devices according to the first embodiment and a comparative example. In FIG. 9, the horizontal axis illustrates the frequency; and the vertical axis illustrates the pass characteristic of a signal using S-parameters of the frequencies. The broken line in FIG. 9 illustrates the characteristic of the electronic device according to the comparative example that does not include the first conductor 41 and the second conductor 42. The solid line illustrates the characteristic of the electronic device 1.

In the simulation illustrated in FIG. 9, the dielectric constant of the main unit 10a is set to 2.2; and the dielectric constant of the lid 10b is set to 4.1. The length L5, the length L6, and the length L7 are set to 2.4 mm. From FIG. 9, it can be seen that the noise of all frequencies from 13.6 to 15.5 GHz are reduced. In particular, it can be seen that the noise can be greatly reduced for the frequencies from 14.0 to 14.5 GHz which is the desired cut-off frequency band in the case where the electronic device 1 is used in a satellite communication application.

### Second Embodiment

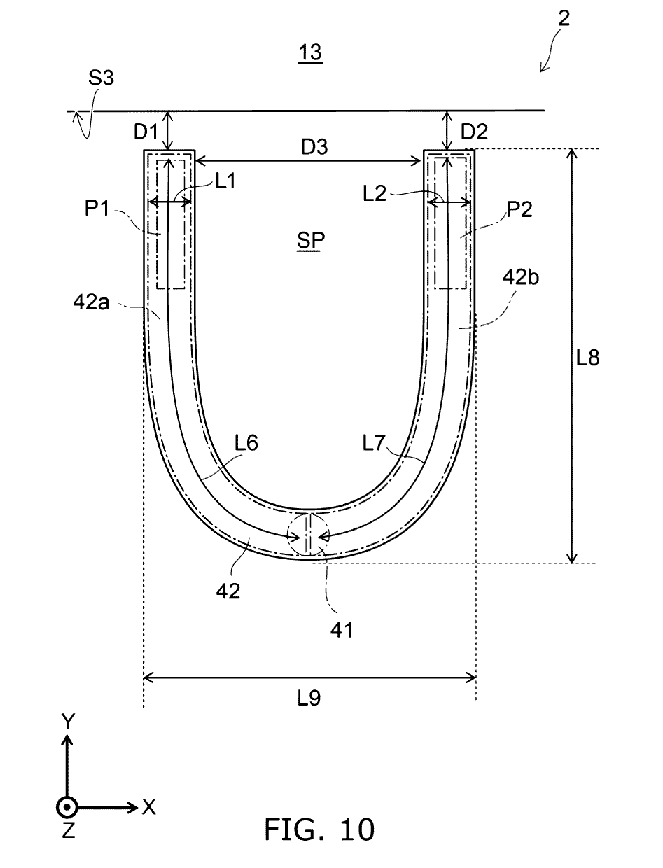

FIG. 10 is an enlarged plan view of a portion of an electronic device 2 according to a second embodiment. In the electronic device 2 according to the second embodiment, for example, the structure of the second conductor 42 is different from the electronic device 1 according to the first embodiment. The configuration and the structure of the electronic device 1 according to the first embodiment are employable for the configuration and the structure of the electronic device 2 according to the second embodiment other than the second conductor 42.

As illustrated in FIG. 10, the second conductor 42 is U-shaped in the embodiment. An end of the first region 42a and an end of the second region 42b are connected to the first conductor 41. The first region 42a includes the first portion P1. The first portion P1 Includes another end of the first region 42a. The second region 42b includes the second portion P2. The second portion P2 includes another end of the second region 42b.

The first portion P1 and the second portion P2 are aligned with the second direction. In other words, the portion at the other end vicinity of the first region 42a and the portion at the other end vicinity of the second region 42b extend parallel to each other. Similarly to the first embodiment, the distance D1 is, for example, shorter than the length L1. The distance D2 is, for example, shorter than the length L2. The distance D1 and the distance D2 are shorter than the distance D3 in the second direction between the first portion P1 and the second portion P2. In the embodiment, the distance D3 is, for example, the distance in the third direction between the other end of the first region 42a and the other end of the second region 42b.

In the example illustrated in FIG. 10, a length L8 in the second direction of the second conductor 42 is longer than a length L9 In the third direction of the second conductor 42. However, the length L9 may be equal to the length L8; and the length L9 may be longer than the length L8.

In the embodiment as well, it is possible to obtain effects similar to those of the first embodiment.

### Third Embodiment

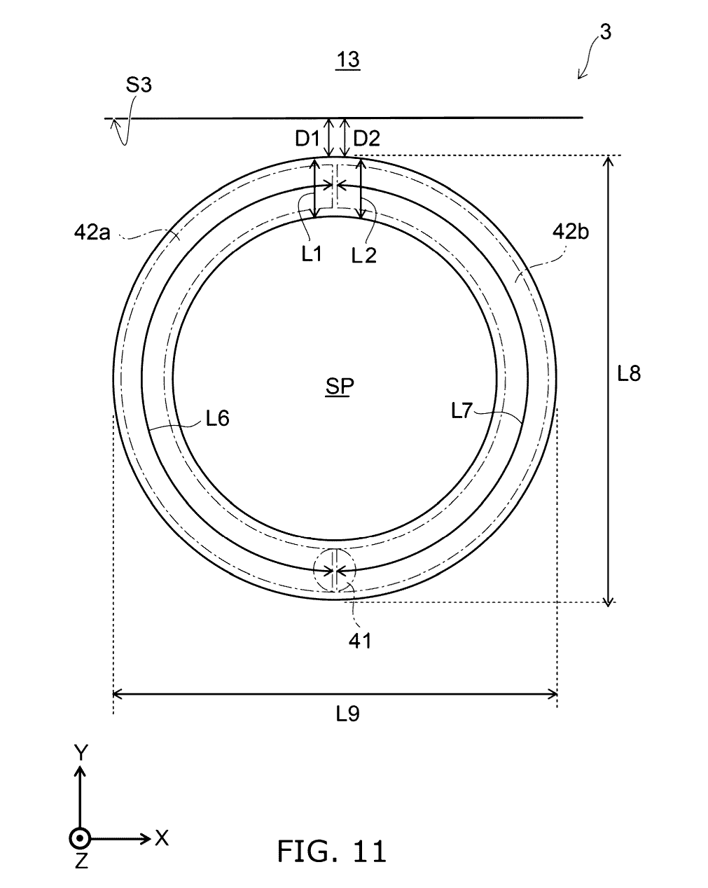

FIG. 11 is an enlarged plan view of a portion of an electronic device 3 according to a third embodiment.

In the electronic device 3 according to the third embodiment, for example, the structure of the second conductor 42 is different from the electronic device 1 according to the first embodiment. The configuration and the structure of the electronic device 1 according to the first embodiment are employable for the configuration and the structure of the electronic device 3 according to the third embodiment other than the second conductor 42.

As Illustrated in FIG. 11, the second conductor 42 is provided in an annular configuration in the embodiment. The opening SP is provided inside the second conductor 42. An end of the first region 42a and an end of the second region 42b are connected to the first conductor 41. Another end of the first region 42a contacts another end of the second region 42b.

For example, the distance D1 in the second direction between the third surface S3 and the other end of the first region 42a is shorter than the length L1 in the second direction of the other end of the first region 42a. For example, the distance D1 in the second direction between the third surface S3 and the other end of the second region 42b is shorter than the length L2 in the second direction of the other end of the second region 42b.

In the example Illustrated in FIG. 11, the length L8 in the second direction of the second conductor 42 is equal to the length L9 in the third direction of the second conductor 42. However, the length L9 may be longer than the length L8; and the length L8 may be longer than the length L9.

In the embodiment as well, it is possible to obtain effects similar to those of the first embodiment.

According to the embodiments described above, an electronic device can be provided in which the noise is suppressed.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, embodiments of the invention are described with reference to specific examples. However, the invention is not limited to these specific examples. For example, one skilled in the art may similarly practice the invention by appropriately selecting specific configurations of components included in the electronic device such as the housing, the electronic component, the first conductor, the second conductor, the third conductor, the metal patch, the via, etc., from known art; and such practice is within the scope of the invention to the extent that similar effects can be obtained.

Further, any two or more components of the specific examples may be combined within the extent of technical feasibility and are included in the scope of the invention to the extent that the purport of the invention is included.

Moreover, all electronic devices practicable by an appropriate design modification by one skilled in the art based on the electronic devices described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An electronic device, comprising:
a housing including
a first plate portion having a first surface,
a second plate portion separated from the first surface in a first direction crossing the first surface, the second plate portion having a second surface aligned with the first surface, and
a third plate portion having a third surface crossing a second direction, the second direction crossing the first direction;
an electronic component provided inside the housing;
a first conductor provided inside the first plate portion; and
a second conductor including a first region and a second region and being provided between the first plate portion and the second plate portion,
an end of the first region being connected to the first conductor, a position in the second direction of at least a portion of the first region being between a position in the second direction of the end of the first region and a position in the second direction of at least a portion of the third plate portion,
an end of the second region being connected to the first conductor, a position in the second direction of at least a portion of the second region being between a position in the second direction of the end of the second region and a position in the second direction of at least a portion of the third plate portion, an opening being provided between at least a portion of the first region and at least a portion of the second region.

2. The device according to claim 1, wherein a distance in the second direction between the first region and the third plate portion is not more than a length in a third direction of at least a portion of the first region, the third direction being perpendicular to the first direction and the second direction.

3. The device according to claim 2, wherein a distance in the second direction between the second region and the third plate portion is not more than a length in the third direction of at least a portion of the second region.

4. The device according to claim 2, wherein
a length in the third direction of at least a portion of the first region is not more than a length in the third direction of at least a portion of the opening, and
a length in the third direction of at least a portion of the second region is not more than the length in the third direction of the at least a portion of the opening.

5. The device according to claim 2, wherein the first region includes a bent portion.

6. The device according to claim 2, wherein
the first region includes a first portion aligned with the second direction, and
the second region includes a second portion aligned with the second direction.

7. The device according to claim 6, wherein
the first region includes a third portion aligned with the second direction,
the second region includes a fourth portion aligned with the second direction, and
a distance in the third direction between the third portion and the fourth portion is greater than a distance in the third direction between the first portion and the second portion.

8. The device according to claim 2, wherein the second conductor contacts the third plate portion.

9. The device according to claim 2, further comprising a third conductor,
the first conductor being provided between the second conductor and the third conductor,
the third conductor being connected to the second conductor.

10. The device according to claim 9, wherein the third conductor is set to a fixed potential.

11. The device according to claim 2, wherein
the first conductor is multiply provided, the plurality of the first conductors being arranged in the third direction,
the second conductor is multiply provided, the plurality of the second conductors being arranged in the third direction, and
the plurality of second conductors is connected respectively to the plurality of first conductors.

12. The device according to claim 11, wherein a distance in the second direction between one of the plurality of second conductors and another of the second conductors most proximal to the one of the second conductors in the second direction is equal to an odd multiple of 2.5 mm or an odd multiple of 5 mm.

13. The device according to claim 2, further comprising:
a fourth conductor; and
a fifth conductor,
the housing further including a fourth plate portion having a fourth surface, the fourth surface crossing the third direction,
the fourth conductor being provided inside the first plate portion,
the fifth conductor being provided between the first plate portion and the second plate portion, the fifth conductor Including a third region and a fourth region,
an end of the third region being connected to the fourth conductor, a position in the third direction of at least a portion of the third region being between the end of the fourth region and a position in the third direction of at least a portion of the fourth plate portion,
an end of the fourth region being connected to the fourth conductor, a position in the third direction of at least a portion of the fourth region being between the end of the fourth region and a position in the third direction of at least a portion of the fourth plate portion.

14. The device according to claim 13, wherein
the fourth conductor is multiply provided, the plurality of the fourth conductors being arranged in the second direction,
the fifth conductor is multiply provided, the plurality of the fifth conductors being arranged in the second direction, and
the plurality of fifth conductors is connected respectively to the plurality of fourth conductors.

15. An electronic device, comprising:
a housing including
a first plate portion having a first surface,
a second plate portion separated from the first surface in a first direction crossing the first surface, the second plate portion having a second surface aligned with the first surface, and
a third plate portion having a third surface crossing a second direction, the second direction crossing the first direction;
an electronic component provided inside the housing;
a first conductor provided inside the first plate portion; and
a second conductor including a first region and a second region and being provided between the first plate portion and the second plate portion,
an end of the first region being connected to the first conductor, another end of the first region contacting the third plate portion,
an end of the second region being connected to the first conductor, another end of the second region contacting the third plate portion, an opening being provided between at least a portion of the first region and at least a portion of the second region.
